(19) United States
(12) Patent Application Publication
(10) Pub. No.: US 2025/0294787 A1
(43) Pub. Date: Sep. 18, 2025

(54) SCALABLE NEUROMORPHIC INTEGRATED CIRCUIT HARDWARE

(71) Applicant: UNM RAINFOREST INNOVATIONS, Albuquerque, NM (US)

(72) Inventors: Payman ZARKESH-HA, Albuquerque, NM (US); Steven R.J. BRUECK, Albuquerque, NM (US); Ganesh BALAKRISHNAN, Albuquerque, NM (US); Tito BUSANI, Albuquerque, NM (US); Alexander NEUMANN, Albuquerque, NM (US)

(21) Appl. No.: 19/080,193

(22) Filed: Mar. 14, 2025

Related U.S. Application Data
(60) Provisional application No. 63/565,206, filed on Mar. 14, 2024.

(51) Int. Cl. H10D 30/01; H10D 30/43

(52) U.S. Cl. CPC H10D 30/014; H10D 30/0411; H10D 30/435

(57) ABSTRACT

Methods for fabricating a semiconductor are disclosed. The methods include creating nanowires of a nanowire type on semiconductor surface, forming grooves in an insulator surface to direct a self-alignment of the nanowires on the insulator surface, converting the insulator surface into the semiconductor of the nanowire type, and isolating the semiconductor by etching the distributed nanowires that are not part of the subset. The converting includes cleaving the nanowires from the semiconductor surface and distributing the nanowires in the grooves, and creating the semiconductor from a subset of the distributed nanowires using a transistor fabrication process.

### CROSS REFERENCE TO RELATED APPLICATIONS

This patent application claims priority to U.S. Provisional Application No. 63/565,206, filed on Mar. 14, 2024, which is incorporated by reference herein in its entirety.

### FIELD

The present teachings relate generally to self-aligned semiconductor nanowire materials and hardware.

### BACKGROUND

Moore's law has been the main driving force behind the microelectronic industry over the past 50 years. In 1971, the first Intel microprocessor contained 2,300 transistors. AMD's MI300X GPU has the current highest transistor count with totaling 153 billion transistors built on TSMC's 5 nm process. This improvement of eight-orders in magnitude of added capability (transistor count) is unheard of in any other industry worldwide. Although the semiconductor industry has made significant efforts over the years to get over hurdles while scaling transistors, the industry is reaching the physical limits of silicon, where a transistor contains a few silicon atoms. 3D integration, where multiple layers of semiconductor chips stack on top of each other to create a single, more powerful chip, is a possible future direction. Over the past two decades, several techniques for 3D integration have been studied, including sea-of-leads (SOL), system-on-a-package (SOP), and through silicon via (TSV). There are commercial products ranging from FPGAs to GPUs that utilize TSVs. TSV-based 3D integration has an asymmetry between the transistor dimensions and the dimensions of the TSVs. Currently, the largest transistor count in flash memory is the Micron Technology's two terabyte solid state drive (SSD) that uses 3D stack of 16-die, 232-layer vertical NAND flash memory chip, with 5.3 trillion floating-gate MOSFETs in a 11.5 mm×13.5 mm package. The SSD uses a vertical stack of transistors built on silicon nanowires in a NAND structure (in series).

What are needed are materials for energy efficient, enhanced-performance and sustainable semiconductor-based systems. What is further needed is a synthetic material using semiconductor nanowires in a reconfigurable neuromorphic integrated circuit that can break the current physical limits in integrated circuits.

### SUMMARY

Neuromorphic hardware uses a brain-inspired architecture to complement deterministic computing hardware with a massively interconnected non-deterministic computing capability. The neuromorphic hardware uses self-aligned semiconductor nanowire materials to create scalable multi-channel floating gate NWFET (FG-NWFET) devices suitable for monolithic 3D integration and neuromorphic systems.

### BRIEF DESCRIPTION OF THE DRAWINGS

FIG. 1 is a pictorial diagram of the fabrication a back-end-of-line (BEOL)-compatible floating gate-nanowire field effect transistor (FG-NWFET) for monolithic 3D integration on a CMOS silicon wafer;

FIG. 2A is a pictorial representation of the structure of the FG-NWFET;

FIG. 2B is a pictorial representation of the top view of the device showing the parameters used in statistical modeling of the device;

FIG. 3A is a graphical representation of an example of probability distribution of nanowires under NWFETs;

FIG. 3B is a table of NWFET design parameters for 1 PPM open defects rate;

FIG. 4 is a pictorial illustration of top-down fabrication of GaN NWs;

FIGS. 5A and 5B are pictorial representations of GaN nanowires (NWs) with a 37 nm diameter (FIG. 5A), and a TEM image of the GaN NWs (FIG. 5A) in which wet etching is used to define the diameter of the NWs;

FIGS. 6A-6F are pictorial illustrations of the Langmur-Blodgett method applied to the fabrication of III-V NWs;

FIG. 7 is a circuit diagram of a synapse circuit designed using FG-NWFET;

FIG. 8 is a pictorial representation of a model of the NWFET perceptron used as the unit cell in recurrent neural network (RNN)/convolution neural network (CNN)-based computations; and

FIG. 9 is a flowchart of a method in accordance with embodiments of the present disclosure.

### DESCRIPTION

Reference will now be made in detail to systems and methods in accordance with embodiments of the present disclosure which are illustrated in the accompanying drawings. Wherever possible, the same reference numbers will be used throughout the drawings to refer to the same, similar, or like parts.

Advanced materials can be fabricated monolithically in a 3D integration technology, where additional transistors are formed right after the back-end-of-line (BEOL) process along with the interconnect layers. To overcome the thermal budget constraint set by the fabrication process, a low-temperature process using semiconductor nanowires suitable for monolithic 3D integration is used. Fabricated semiconductor nanowires are used to develop a low-temperature process to create nanowire field effect transistors (NWFETs). NWFETs can be used for non-deterministic computing (e.g., in neuromorphic architectures: very large-scale integrated circuits that mimic neuro-biological systems), where defects can be tolerated with massively interconnected NWFETs made in a monolithic 3D integration.

Embodiments in accordance with the present disclosure include, but are not limited to including, scalable neuromorphic integrated circuit hardware capable of performing highly efficient non-deterministic computing in conjunction with digital microprocessors, developed using devices compatible with monolithic 3D integration. Embodiments in accordance with the present disclosure include a synthetic material (semiconductor nanowire layer), device (FG-NWFET), and system (reconfigurable neuromorphic integrated circuit) that extend the physical limits of integrated circuits.

The synthetic material created in accordance with embodiments of the present disclosure can be used as semiconductor nanowires in a reconfigurable neuromorphic integrated circuit. The material is fabricated monolithically using 3D integration technology, where additional transistors are formed right after the back-end-of-line (BEOL) process along with the interconnect layers. Embodiments in accordance with the present disclosure include a low-temperature process using semiconductor nanowires suitable for monolithic 3D integration. The fabricated semiconductor nanowires are used in a low-temperature process to create NWFETs that are used, for example, for non-deterministic computing (e.g., in neuromorphic architectures: very large-scale integrated circuits that mimic neuro-biological systems).

Embodiments in accordance with the present disclosure cleave the nanowires and distribute them on an insulator surface using a self-aligned technique, converting the surface into a high-quality semiconductor layer in a BEOL-compatible (low temperature) process suitable for monolithic 3D integration. Other types of nanowires besides silicon-only nanowires are possible to use. The nanowire layer can be made from semiconductor materials such as GaN, GaAs, and SiC that can be used for various applications including high efficiency detectors, LEDs, sensors, high-power and high-speed RF circuits and more. Multiple neuromorphic layers can be added.

The neuromorphic hardware is based on vector matrix multiplication in a crossbar fashion which computes a sum of products. To store weights, the neuromorphic circuit utilizes a multi-channel FG-NWFET fabricated on the nanowire layer, where the charges stored in the floating gate control the conductivity of NWFETs, thereby defining the weights. Massive parallelism and reconfigurability renders the neuromorphic hardware fault-tolerant. The neuromorphic hardware includes 1) reconfigurable and scalable neuromorphic architecture similar to an FPGA, 2) built-in analog signal processing units capable of highly efficient non-deterministic computing, and 3) utilization of advanced devices that are compatible with monolithic 3D integration and tolerant of fabrication imperfections. For instance, a deep neural network process that is currently implemented digitally in a microprocessor can be implemented directly in the neuromorphic circuit that uses the FG-NWFETs.

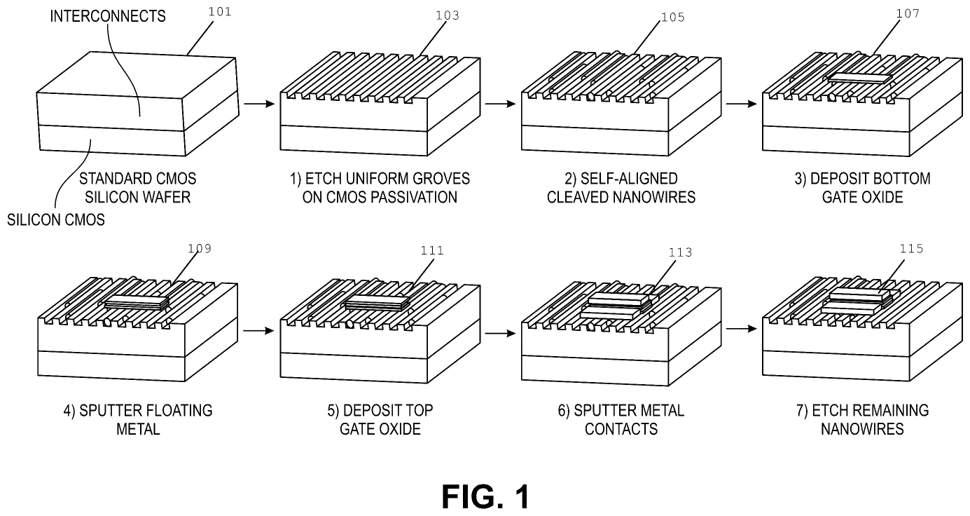

Referring now to FIG. 1, the process to fabricate a monolithically integrated FG-NWFET on top of silicon CMOS wafer 101 is shown. The process includes etching 103 uniform grooves to direct the self-assembly of nanowires on the surface producing self-aligned cleaved nanowires 105. The process includes depositing 107 the bottom gate oxide, sputtering 109 the floating metal, depositing 111 the top gate oxide, and sputtering 113 the terminal contacts. The process ends by etching 115 the remaining nanowires to isolate the FG-NWFETs. Sputtering 109 floating metal and depositing 111 top gate oxide can be omitted to fabricate other NWFETs. The fabrication process provides a scalable and sustainable synthesis for low-temperature and energy-efficient manufacturing, which can reduce clean-water usage and chemical wastes.

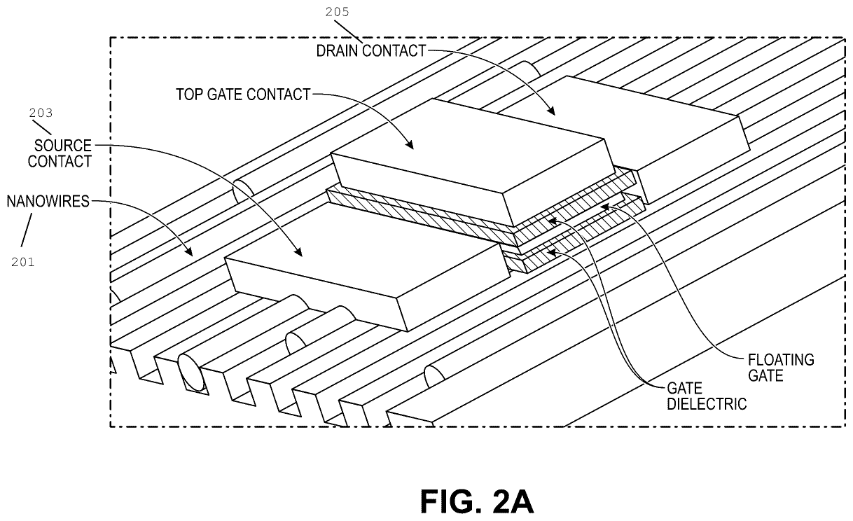

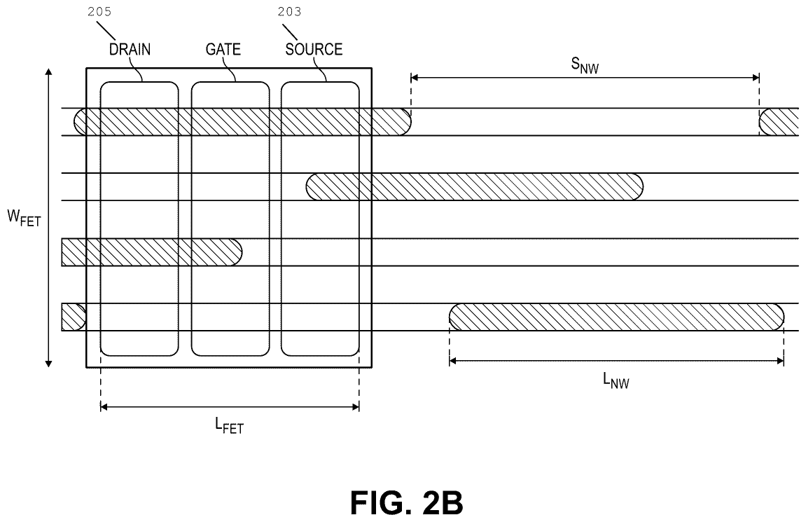

Referring now to FIGS. 2A and 2B, the FG-NWFET device is currently used for vertical integration in SSD and flash memories. To extend this capability to non-memory circuit topologies (including neuromorphic circuits), a FG-NWFET on a self-aligned nanowire layer 201 as shown in FIG. 2A is created. This approach provides a solution for 3D monolithic integration on CMOS wafers. In the top view diagram shown in FIG. 2B, one of four nanowires contributes into the device current. Using statistical modeling, it can be shown that the probability of a single filled grove under the NWFET is,

$$P s = ( {L}_{NW} - {L}_{FET} ) / ( {L}_{NW} + {S}_{NW} - {L}_{FET} ) \qquad ( 1 )$$

where Ps is the probability of a single filled grove under the NW_{FET}, L_{NW} is the length of the nanowires, S_{NW} is the average spacing between nanowires and, L_{FET} is the transistor length as shown in FIG. 2B. In some configurations, the nanowires are the same length as each other, whereas their spacing is a random parameter that can be estimated from the nanowire density, d=L_{NW}/(L_{NW}+S_{NW}). Using Equation (1) and the binomial distribution, the probability of nanowire count distribution in an N-channel NWFET becomes:

$${P}_{N W} ( k ) = ( N ! / ( k ! ( N - k ) ! ) ) * {( P s )}^{k} {( 1 - P s )}^{N - k} \qquad ( 2 )$$

where P_{NW}(k) is the probability of having k nanowires under the NWFET, Nis the total number channels (grooves) under the device, and Ps is the probability of single filled groove from Equation (1).

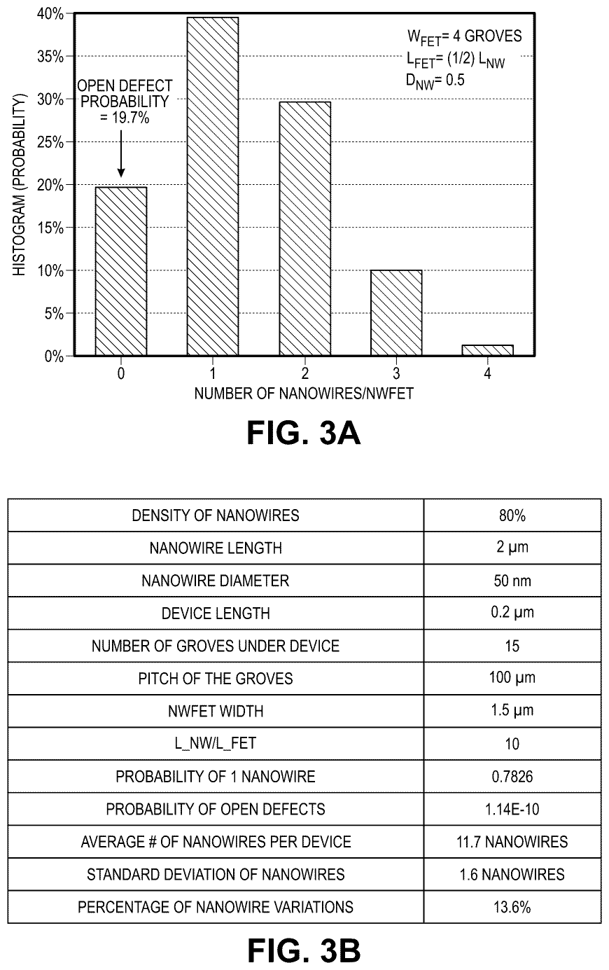

Referring now to FIGS. 3A and 3B, for illustration purposes, an example of nanowire-count distribution in a 4-channel NWFET is shown in FIG. 3A, assuming the length of the device is ½ of the nanowire length with the nanowire density of 50%. The nanowire count distribution in Equation (2) provides three specifications for the NWFET device, including: 1) the probability of open defects, P_{Open}; 2) the average number of nanowires under the NWFET, Avg(N_{NW} and 3) the variation of the nanowires counts in the NWFET, σ_{NW}*(N_{NW}), as shown below.

$${P}_{Open} = {( 1 - P s )}^{N} \qquad ( 3 )$$

$$Avg ( {N}_{NW} ) = NPs \qquad ( 4 )$$

$$variation = {σ}_{{NW}^{*}} A v g ( {N}_{NW} ) = √ ( ( 1 - Ps ) / {N}_{P s} ) \qquad ( 5 )$$

where Ps is the probability of the single filled grove as shown in Equation (1) and Nis the number of channels in the NWFET. In some configurations, the physical parameters for an NWFET are designed such that the probability of open defects is limited to 0.1 part per billion (PPB). Based on the statistical model in Equation (3), a solution can be achieved with a 15-channel NWFET over 2 μm self-aligned nanowires that are distributed randomly on 100 nm pitch groves with nanowire density of 80% as shown in FIG. 3B. In this example, the 15-channel NWFET device length and NWFET width are 0.2 μm and 1.5 μm, respectively. Also, as shown in FIG. 3B, in some configurations, the device systematic variation is 13.6%, which is comparable to the random variations in CMOS devices. In some configurations, the device's physical parameters are optimized based at least on materials, devices, cost, scalability, and energy efficiency.

Nanowires provide high-quality semiconductor materials for many device applications. Nanowires are available in a wide range of high-quality semiconductor materials including Si, Ge, and a wide variety of III-V binary (e.g., GaAs, GaN, SiC) as well as alloy materials that can be tailored for specific applications. In addition to the materials, doping configurations (e.g., np, npn, pnp) can be incorporated into the nanowires, further extending the flexibility of the architecture. Multiple neuromorphic layers, for example n-type on one layer and p-type on a second interconnected layer can also be provided for added functionality.

One aspect of embodiments in accordance with the present disclosure is a fabrication process that: 1) is low temperature to provide compatibility with fabricated CMOS ICs, and 2) is readily scalable to volume manufacturing. Semiconductor growth involves high temperature budgets which are not compatible with prefabricated CMOS wafers with extensive interconnect and fill metallization. Embodiments in accordance with the present disclosure fabricate the nanowires on a separate wafer and transfer them with a directed self-aligned process atop of the passivation layer.

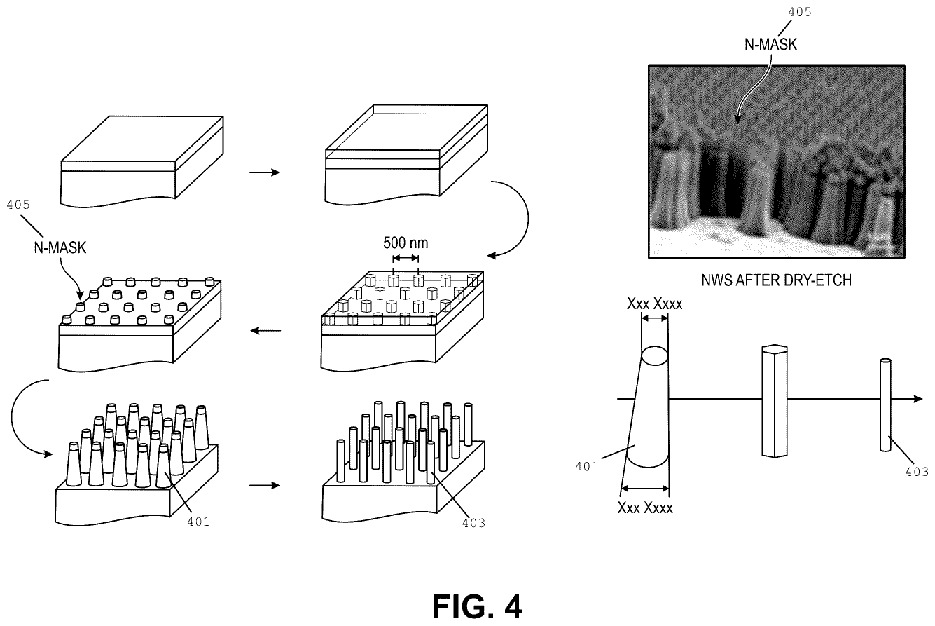

Referring now to FIG. 4, in some configurations, two types of nanowire material serve as channels. GaN and III-V nanowires are grown with different aspect ratios and doping concentrations to be suitable for channel configuration and channel dimensions to fulfill fabrication technology and to reduce manufacturing costs. The process presented herein for GaN and GaAs nanowires is similar to process sequences available for other semiconductor materials. High-quality (impurity level in the order of 1016 atoms/cm3) and high aspect ratio nanowires are fabricated by a two-step procedure: 1) an inductive-coupled plasma (ICP) is dry etched (C12 based) using a Ni metal mask, and 2) a maskless, facet-selective is wet etched (KOH and AZ 400 developer). The dry etch is used to form isolated structures with sloped sidewalls 401 and material etch damage, while the wet etch is employed to eliminate the damage from the ICP etch and provide NWs with nearly atomically smooth sidewalls 403 and controllable diameters. A Ni mask 405 is used to define the initial NWs diameter. In some configurations, interferometric lithography can be used to produce large-area patterns. In some configurations, 193-nm lithography tools are used.

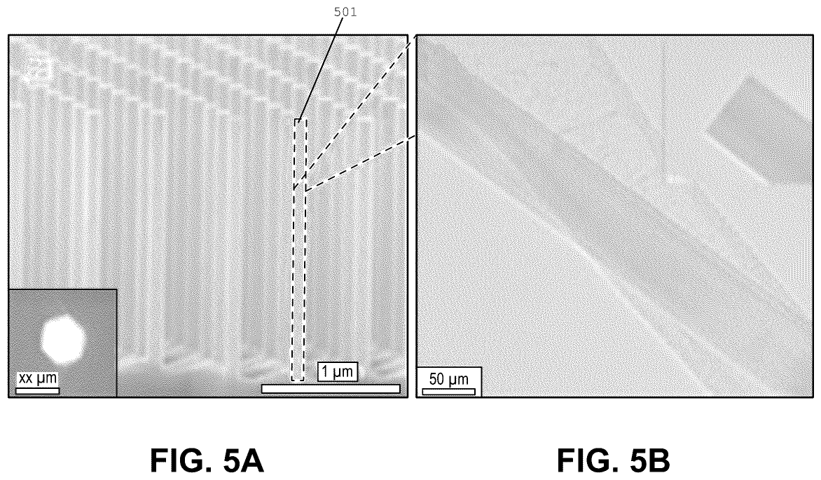

Referring now to FIGS. 5A and 5B, in some configurations, an aspect ratio of 36 is obtained with diameter of 37 nm for the nanowires 501 as shown in FIG. 5A. The sidewall quality of the fabricated nanowire can be inspected by using transmission electron microscopy (TEM), showing a quality equal to single crystal structures as shown in FIG. 5B.

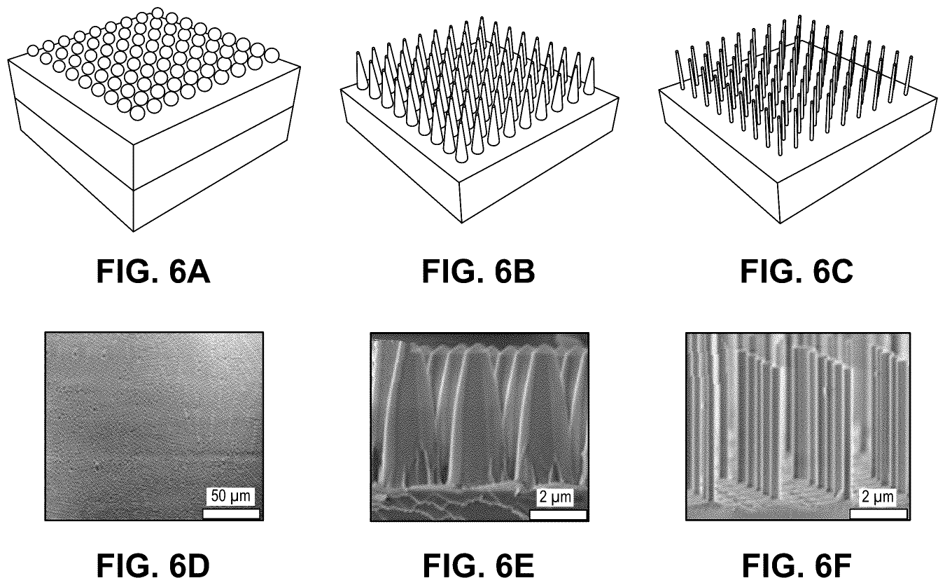

Referring now to FIGS. 6A-6F, for the III-V NWS, the use of Langmuir-Blodgett techniques to form a close-packed monolayer of silica microspheres (FIGS. 6A and 6D) which defines arrays of cylindrical nanowires is shown. Subsequently, the mask geometry is transferred into the epilayer by the ICP dry etch, with the etch depth controlled by the duration of the etch. After the etch, tapered-shaped nanostructures (FIGS. 6B and 6E) are formed with severe surface damage and roughness. An anisotropic wet etch is used to selectively etch the structures to get straight and smooth sidewalls (FIGS. 6C and 6F). The method can be used to control lateral bandgaps as well as doping profiles. This is achieved by creating such doping profiles in the wafer through either epitaxial processes or using techniques such as implantation of dopants. The epitaxial process can be useful for introducing bandgap changes or doping gradients including structures such as pnp or npn.

The nanowires shown in FIG. 5A and FIG. 6F can be removed from the substrate using either under etching or by sonication. In some configurations, in the CMOS neuromorphic design, the channel is composed of nanowires 201 (FIGS. 2A and 2B) and the source contacts 203 (FIGS. 2A and 2B) and drain contacts 205 (FIGS. 2A and 2B) are “top down” contacts. The length of the channel is approximately 200 nm and the nanowires are ˜1-2 mm. The channel conductivity is dependent on the side walls quality of the nanowires and the ohmic contacts. In some configurations, a sonication method can remove the nanowires from the substrate. Etching is also possible. After sonication the nanowires are transferred to the target wafer.

The target wafer on which the devices are self-assembled includes a fully fabricated CMOS wafer with a dielectric passivation layer. A series of parallel grooves is fabricated on the surface of the passivation layer. When a drop of water interacts with this a photoresist surface, elongation along the lines is evident. The extent of the elongation depends on the details of the surface interactions between the liquid and the substrate material. If nanowires are suspended in the liquid applied to the surface, spin coating forces them to align along the grooves. For example, a polydisperse ensemble of nominally 80 nm diameter silica spherical nanoparticles is arrayed into ˜80 nm wide grooves on a SiO₂ surface. This produces large arrays of nanowires, ordered in the sense that they are directed along the grooves in various positions. These nanowires are suitable for unipolar transistors. Localization is possible with the addition of barriers perpendicular to the groove. Matching the length of these sub-grooves to the uniform nanowire length can provide ordering which allows the use of doped nanowires (npn or pnp) that provide circuit flexibility. Other parameters that are considered in the process include concentrations, surface and solution chemistry, and spin profiles (speed and ramp).

An alternative approach to directed self-assembly is dipping a grooved wafer into a solution containing nanowires at an angle close to vertical and pulling the wafer from the solution, similar to Langmuir Blodgett film preparation. In some configurations, the processes described herein operate at low temperatures (<70° C.). Specifically, the thin films serve solely as sacrificial material for fabricating the nanowires, which are then transferred to the desired device.

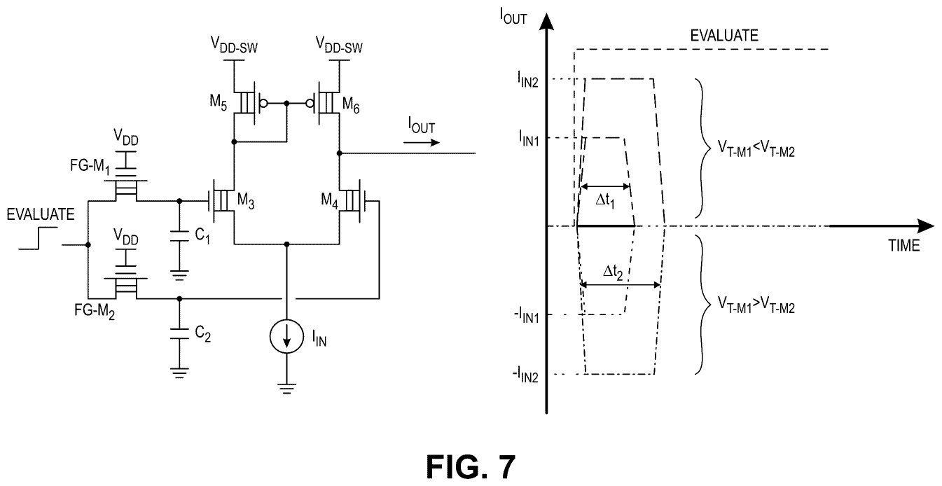

Referring now to FIG. 7, in some configurations, the neuromorphic integrated circuit can be implemented in an analog domain. An example of a synapse using NWFET, shown in FIG. 7, indicates that the weights are implemented using time delay difference in a differential amplifier to create a pulse width modulation that performs multiplication. The current of a synapse is then added or subtracted in a capacitor, which converts the charge into a voltage that is proportional to the sum of weighted inputs. At the rising edge of the Evaluate pulse, a pulsed current is generated in the output of the differential amplifier, where its amplitude is the input current, Iin, and its width, Δt, depends on the difference in the threshold voltages of FG-M1 and FG-M2, ΔVT, which is programmed during the neuron training process.

Embodiments in accordance with the present disclosure can include a hierarchical system-level simulator that is focused on the integration of NWFETs within neuromorphic circuits. For example, at the neuromorphic architectural level are feed-forward Multilayer Perceptrons (MLP), Spiking Neural Networks (SNNs), Convolution Neural Networks (CNNs), Recurrent Neural Networks (RNNs), and Transformer Networks. At the circuit level, the neuromorphic circuit choices for these system-level approaches can be floating gate crossbar arrays, memristor systems, phase-change memory-based systems, CMOS-based dynamic and static circuit implementations.

At least three classes of applications can be implemented using the proposed the nanowire neuromorphic architecture: 1) machine learning, 2) optimization, and 3) data-driven modeling and system identification. Application-level performance analysis allows for the understanding and quantification the performance of applications in the presence of the uncertainty associated NWFET neuromorphic architecture, and allows for the use of the analysis as a guide for establishing hardware performance requirements. In the machine-learning application, classification based on convolutional neural networks (CNNs) and recurrent neural networks (RNNs), as well as classification with a known (specified) classification rule are addressed. In the optimization category, combinatoric (L0) optimization with specified objective functions is addressed. In the data-driven modeling category, estimating transition probabilities of complex systems whose dynamics are modeled by Markov chains is addressed.

The performance analysis of the applications includes quantifying the performance of the NWFET perceptron, constituting one-iteration of a RNN or single layer of a CNN, probabilistically while factoring in the uncertainty associated with the weights at the gates, and, in the case of unit-cells with defects, the stochastic number and location of open/shorted weights (e.g., corresponding to absence of NWFETs). The quantification provides the ₘₑₐₙ-square error (MSE) associated with the output of a NWFET perceptron, RNN and CNN as a function of the defect probabilities, density of nanowires, and the signal-to-noise ratio of the analog signals. The probabilities described in Equations (1)-(5) are used as an input to the unit-cell analysis, producing the probability distribution of the unit-cell while capturing the uncertainties associated with the unit cell. At the second stage of the analysis, the RNN and CNN performance predictions are embedded in an application whose performance (in terms of classification error, for example) is assessed in terms of the MSE of the RNN/CNN that executes an application. The completion of the second step results in a mapping between the performance of the application to the design and fabrication parameters associated with NWFET.

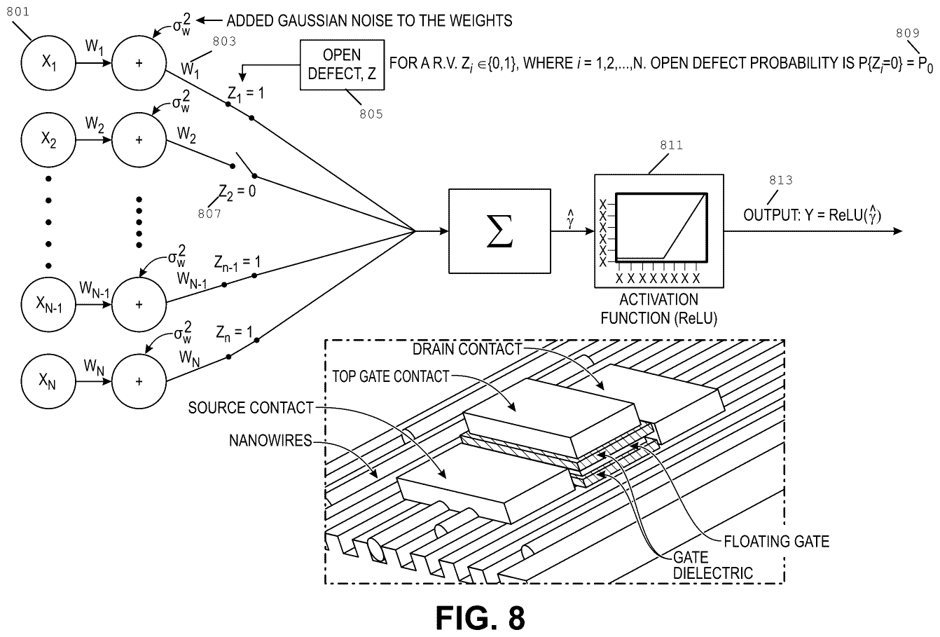

Referring now to FIG. 8, a schematic of the NWFET perceptron is shown, illustrating the uncertainties specific to the NWFET hardware. The inputs 801, X=(X₁, X₂, . . . , Xₙ), to the perceptron are multiplied by the analog weights 803, W=(W₁, W₂, . . . , Wₙ), which are controlled by the gate voltage. In the event of an open-circuit (defective) NWFET 805 at any of the n inputs, the flow of the input is interrupted. The impact of the defect 805 on computing is captured by a parameter, Zᵢ (for the ith input), a random variable 807 that is multiplied by the weight 803 Wᵢ. If the NWFET is defective as an open circuit then Zᵢ=0, otherwise, Zᵢ=1 and the operation of the particular input to the perceptron is unaffected. The open-circuit probability 809, Pₒ, is a design parameter. The uncertainty in the weights 803, due to noise, quantization, and imprecise control of the gate voltage, are modeled by assuming that the weights 803 are random variables whose means are the intended (noiseless, perfect weights) weight and the variance (σW₂) representing the total uncertainty. In some configurations, the activation function 811, rectified linear unit (ReLU), is considered as the perceptron nonlinearity, which can be implemented electronically. The output 813 of the ReLU unit is the output of the perceptron. The MSE is characterized in the perceptron output as a function of the defect's probability and the uncertainties in the weights, for a given input. The method of characteristic functions is used to determine the probability distribution of the output Z for the NWFET perceptron. Large-deviation theory is used to determine the probability of deviating from the ideal NWFET perceptron in the limit when massive parallelization is utilized (i.e., when the number of weights is very large, corresponding to CNNs for deep learning).

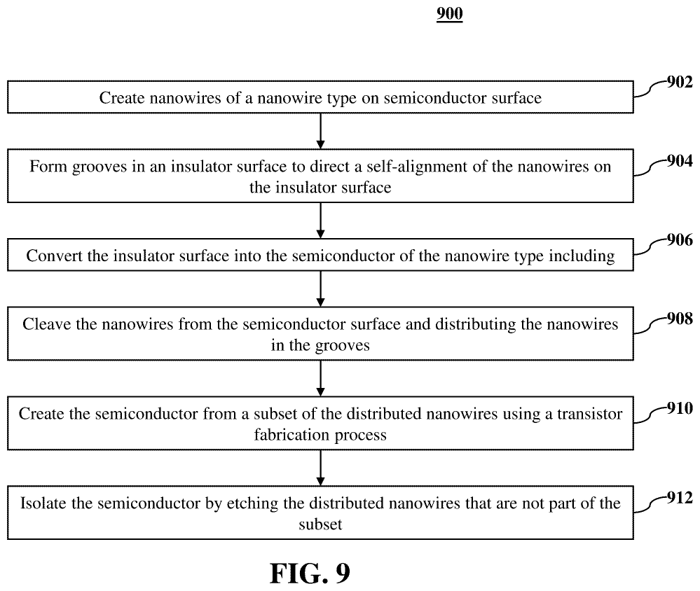

Referring now to FIG. 9, a method 900 for fabricating a semiconductor includes, but is not limited to including, creating 902 nanowires of a nanowire type on semiconductor surface, forming 904 grooves in an insulator surface to direct a self-alignment of the nanowires on the insulator surface, and converting 906 the insulator surface into the semiconductor of the nanowire type. The converting includes cleaving 908 the nanowires from the semiconductor surface and distributing the nanowires in the grooves, and creating 910 the semiconductor from a subset of the distributed nanowires using a transistor fabrication process. The method 900 includes isolating 912 the semiconductor by etching the distributed nanowires that are not part of the subset.

While the present teachings have been illustrated with respect to one or more implementations, alterations and/or modifications may be made to the illustrated examples without departing from the spirit and scope of the appended claims. For example, it may be appreciated that while the process is described as a series of acts or events, the present teachings are not limited by the ordering of such acts or events. Some acts may occur in different orders and/or concurrently with other acts or events apart from those described herein. Also, not all process stages may be required to implement a methodology in accordance with one or more aspects or embodiments of the present teachings.

It may be appreciated that structural objects and/or processing stages may be added, or existing structural objects and/or processing stages may be removed or modified. Further, one or more of the acts depicted herein may be carried out in one or more separate acts and/or phases. Furthermore, to the extent that the terms “including,” “includes,” “having,” “has,” “with,” or variants thereof are used in either the detailed description and the claims, such terms are intended to be inclusive in a manner similar to the term “comprising.” The term “at least one of” is used to mean one or more of the listed items may be selected.

Further, in the discussion and claims herein, the term “on” used with respect to two materials, one “on” the other, means at least some contact between the materials, while “over” means the materials are in proximity, but possibly with one or more additional intervening materials such that contact is possible but not required. Neither “on” nor “over” implies any directionality as used herein. The term “conformal” describes a coating material in which angles of the underlying material are preserved by the conformal material. The term “about” indicates that the value listed may be somewhat altered, as long as the alteration does not result in nonconformance of the process or structure to the illustrated embodiment. The terms “couple,” “coupled,” “connect,” “connection,” “connected,” “in connection with,” and “connecting” refer to “in direct connection with” or “in connection with via one or more intermediate elements or members.” Finally, the terms “exemplary” or “illustrative” indicate the description is used as an example, rather than implying that it is an ideal.

Other embodiments of the present teachings may be apparent to those skilled in the art from consideration of the specification and practice of the disclosure herein. It is intended that the specification and examples be considered as exemplary only, with a true scope and spirit of the present teachings being indicated by the following claims.

1. A method for fabricating a semiconductor comprising:
creating nanowires of a nanowire type on semiconductor surface;
forming grooves in an insulator surface to direct a self-alignment of the nanowires on the insulator surface;
converting the insulator surface into the semiconductor of the nanowire type including:
cleaving the nanowires from the semiconductor surface and distributing the nanowires in the grooves; and
creating the semiconductor from a subset of the distributed nanowires using a transistor fabrication process; and
isolating the semiconductor by etching the distributed nanowires that are not part of the subset.

2. The method of claim 1, wherein the semiconductor is a floating gate nanowire field effect transistor (FG-NWFET).

3. The method of claim 1, wherein the nanowire type comprises:
silicon, GaN, GaAs, or SiC.

4. The method of claim 1, wherein the converted insulator surface comprises:
a CMOS wafer with a dielectric passivation layer.

5. The method of claim 1, wherein converting the insulator surface comprises:
using a back-end-of-line-compatible low temperature process suitable for monolithic 3D integration.

6. The method of claim 1, wherein the semiconductor comprises:
one or more of the semiconductors stacked upon each other.

7. The method of claim 1, wherein the transistor fabrication process comprises:
depositing bottom gate oxide on the grooves and the nanowires;
sputtering floating metal on the bottom gate oxide and the nanowires;
depositing top gate oxide on the floating metal and the nanowires; and
sputtering metal contacts on the top gate oxide and the nanowires forming covered nanowires.

8. The method of claim 7, further comprising:
fabricating a multi-channel semiconductor on the nanowires; and
controlling a conductivity of the multi-channel semiconductor that defines weights by storing charges in the floating metal.

9. The method of claim 1, wherein the self-alignment comprises:
suspending the nanowires in a liquid applied to the insulator surface; and
spin coating the nanowires so that the nanowires align along the grooves in the insulator surface.

10. The method of claim 1, further comprising:
providing barriers perpendicular to the grooves to enable localization of the nanowires.

11. The method of claim 1, wherein the nanowires comprise:
bead-shaped artifacts.

12. A method for fabricating a transistor on a grooved surface, the grooved surface including nanowires of a nanowire type placed on an insulator surface, the method comprising:
fabricating the transistor on the grooved surface using a transistor fabrication process; and
isolating the transistor by etching the grooved surface around the transistor.

13. The method of claim 12, wherein the transistor comprises:
a monolithically integrated floating gate nanowire field effect transistor (FG-NWFET).

14. The method of claim 12, wherein the transistor comprises:
a CMOS wafer with a dielectric passivation layer.

15. The method of claim 12, wherein the nanowire type comprises:
silicon, GaN, GaAs, or SiC.

16. The method of claim 12, wherein fabricating the transistor comprises:
using a back-end-of-line-compatible low temperature process suitable for monolithic 3D integration.

17. The method of claim 12, wherein the transistor fabrication process comprises:
depositing bottom gate oxide on the grooved surface;
sputtering floating metal on the bottom gate oxide and the grooved surface;
depositing top gate oxide on the floating metal and the grooved surface; and
sputtering metal contacts on the top gate oxide and the grooved surface.

18. The method of claim 17, further comprising:
fabricating a multi-channel semiconductor on the grooved surface; and
controlling a conductivity of the multi-channel semiconductor that defines weights by storing charges in the floating metal.

19. A neuromorphic integrated circuit comprising:
a multi-channel transistor fabricated by a process including:
creating nanowires of a nanowire type on a semiconductor surface;
forming grooves in an insulator surface to direct a self-alignment of nanowires on the insulator surface;
converting the insulator surface into the neuromorphic integrated circuit of the nanowire type including:
cleaving the nanowires from the semiconductor surface and distributing the nanowires in the grooves; and
creating the semiconductor from a subset of the distributed nanowires using a transistor fabrication process; and
isolating the neuromorphic integrated circuit by etching the distributed nanowires that are not part of the subset.

20. The neuromorphic integrated circuit of claim 19 comprising:
a reconfigurable circuit.
